(19) United States
(12) Patent Application Publication
(10) Pub. No.: US 2017/0279070 A1
(43) Pub. Date: Sep. 28, 2017

(54) ENCAPSULATION APPARATUS

(71) Applicants: BOE TECHNOLOGY GROUP CO., LTD., Beijing (CN); HEFEI XINSHENG OPTOELECTRONICS TECHNOLOGY CO., LTD., Anhui (CN)

(72) Inventors: Xinxin Wang, Beijing (CN); Ronggang Shangguan, Beijing (CN); Wenbin Jia, Beijing (CN); Rui Peng, Beijing (CN); Zhijie Ye, Beijing (CN); Lifang Song, Beijing (CN)

(21) Appl. No.: 15/226,500

(22) Filed: Aug. 2, 2016

(30) Foreign Application Priority Data
Mar. 23, 2016 (CN) 201610169152.3

(51) Int. Cl. H01L 51/52; B05B 1/28; H01L 51/56

(52) U.S. Cl. CPC H01L 51/5237; H01L 51/56; B05B 1/28

(57) ABSTRACT

An encapsulation apparatus includes an attraction unit and n adhesive-dripping units, n being greater than or equal to 1. Each of the adhesive-dripping units contains adhesive glue, the adhesive glue including an absorbable substance. The attraction unit is disposed on a base platform, the attraction unit being configured to generate attraction for the absorbable substance in the adhesive glue sprayed out from a nozzle, such that the adhesive glue is sprayed to dotting positions of the adhesive glue on an encapsulation substrate in a preset spraying amount under the effect of the attraction.

### CROSS REFERENCE TO RELATED APPLICATIONS

This application claims priority to Chinese Patent Application No. 201610169152.3, filed on Mar. 23, 2016, the disclosure of which is incorporated herein by reference in its entirety.

### BACKGROUND

Embodiments of the present disclosure relate to the field of display technology, more particularly, to an encapsulation apparatus.

In recent years, the service life of an organic light-emitting diode (OLED) display is easily affected by water vapor in a surrounding environment which enters into the OLED display. If the OLED display is sealed in an environment free from water vapor, the service life of the OLED display will be prolonged prominently. Therefore, the encapsulation technique of the OLED display becomes a key process for increasing the service life of the OLED display.

In the prior art, it is common to use an epoxy resin-dam filler encapsulation (also called plane encapsulation) process to encapsulate the OLED display. Specially, first an encapsulation substrate is placed on a base platform, then a dam sealant is coated on the encapsulation substrate, then filler glue is filled inside the dam sealant by adhesive-dripping units. The dam sealant is ring-shaped, and the filler glue is sprayed to designated positions from the nozzles of the glue ports of the adhesive-dripping units. The designated positions are also called dotting positions. Finally, the encapsulation substrate filled with the filler glue and the base substrate provided with OLED devices are pressed together and cured.

Since during the above encapsulation process, part of the filler glue is easily adhered at the nozzles of the glue ports of the adhesive-dripping units, the filler glue cannot be sprayed to the dotting positions of the encapsulation substrate completely, which causes a lack of filler glue at the dotting positions on the encapsulation substrate. Therefore, the encapsulation effect is poor and the encapsulation efficiency is low.

### SUMMARY

An encapsulation apparatus is provided, wherein the encapsulation apparatus comprises: an attraction unit and n adhesive-dripping units, n being greater than or equal to 1;

each of the adhesive-dripping units contains adhesive glue, the adhesive glue including an absorbable substance;

the attraction unit is disposed on a base platform, and is configured to generate attraction for the absorbable substance in the adhesive glue sprayed out from nozzles of the adhesive-dripping units, such that the adhesive glue is sprayed to dotting positions of the adhesive glue on an encapsulation substrate in a preset spraying amount under the effect of the attraction.

Optionally, the absorbable substance is a ferromagnetic sub stance;

the attraction unit comprises a plurality of electromagnet groups arranged in an array, each of the electromagnet groups comprising n electromagnets, the n electromagnets being configured to generate attraction for the absorbable substance in the adhesive glue sprayed out from the nozzle after being energized, and stop generating attraction for the absorbable substance in the adhesive glue sprayed out from the nozzle after being de-energized.

Optionally, an orthogonal projection of each electromagnet on the encapsulation substrate corresponds to a dotting position of the adhesive glue on the encapsulation substrate.

Optionally, the absorbable substance is a ferromagnetic substance; the attraction unit comprises a plurality of electromagnet groups arranged in an array, each of the electromagnet groups comprising two electromagnets, the two electromagnets being configured to generate attraction for the absorbable substance in the adhesive glue sprayed out from the nozzles after being energized, and to stop generating attraction for the absorbable substance in the adhesive glue sprayed out from the nozzle after being de-energized, the two electromagnets being located at both sides of the region of the orthogonal projection of the encapsulation substrate on the base platform, and the direction of the resultant force of the attractions generated by the two electromagnets for the absorbable substance in the adhesive glue is the same as the direction of gravity on the adhesive glue sprayed out from the nozzle.

Optionally, the plurality of electromagnet groups are disposed on a carrying surface of the base platform, the carrying surface being configured to carry the encapsulation substrate;

or, the plurality of electromagnet groups are disposed on a surface of the base platform opposite to the carrying surface.

Optionally, the encapsulation apparatus further comprises a current generating unit,

the current generating unit is configured to generate currents of different magnitudes,

the electromagnets in each electromagnet group are further configured to, after being energized, generate different attractions for the absorbable substance in the adhesive glue sprayed out from the nozzle under the control of the currents of different magnitudes.

Optionally, the electromagnet is circular-shaped, and the diameter of the electromagnet is 1 cm.

Optionally, the adhesive glue is a dam filler glue.

The present disclosure provides an encapsulation apparatus, and encapsulation apparatus comprises: an attraction unit and n adhesive-dripping units, n being greater than or equal to 1; the adhesive-dripping units contain adhesive glue; since the adhesive glue contains an absorbable substance, the attraction units can generate attraction for the absorbable substance in the adhesive glue sprayed out from the nozzles of the glue ports of the adhesive-dripping units; the adhesive glue is sprayed to dotting positions of the adhesive glue on a encapsulation substrate in a preset spraying amount under the effect of the attraction. Compared with the prior art, the adhesive glue is not easily adhered at the nozzles of the glue ports of the adhesive-dripping units, thus enhancing the effect and efficiency of encapsulation.

It should be understood that the above general description and the following detailed description are merely schematic and illustrative, not restricting the present disclosure.

### BRIEF DESCRIPTION OF THE DRAWINGS

In order to describe the present disclosure, the following will briefly describe the accompanying drawings used in the description of the embodiments of the present disclosure. Obviously, the accompanying drawings in the following description are merely some embodiments of the present disclosure. To those of ordinary skill in the art, other embodiments may also be obtained based on these accompanying drawings without any creative effort.

FIG. 1 is a structural schematic view of an encapsulation apparatus provided by an embodiment of the present disclosure;

FIG. 2 is a structural schematic view of another encapsulation apparatus provided by an embodiment of the present disclosure;

FIG. 3 is a structural schematic view of an attraction unit provided by an embodiment of the present disclosure;

FIG. 4 is a side view of the attraction unit shown in FIG. 3;

FIG. 5 is a side view of another attraction unit provided by an embodiment of the present disclosure;

FIG. 6 is a structural schematic view of another encapsulation apparatus provided by an embodiment of the present disclosure.

The above accompanying drawings have illustrated embodiments of the present disclosure, and the following will describe them in detail. The accompanying drawings and the description are not intended to restrict the scope of the present disclosure in any way, but rather to describe the concept of the present disclosure for those skilled in the art by referring to specific embodiments.

### DETAILED DESCRIPTION

In order to make the present disclosure more clear, the following will describe in more detail embodiments of the present disclosure.

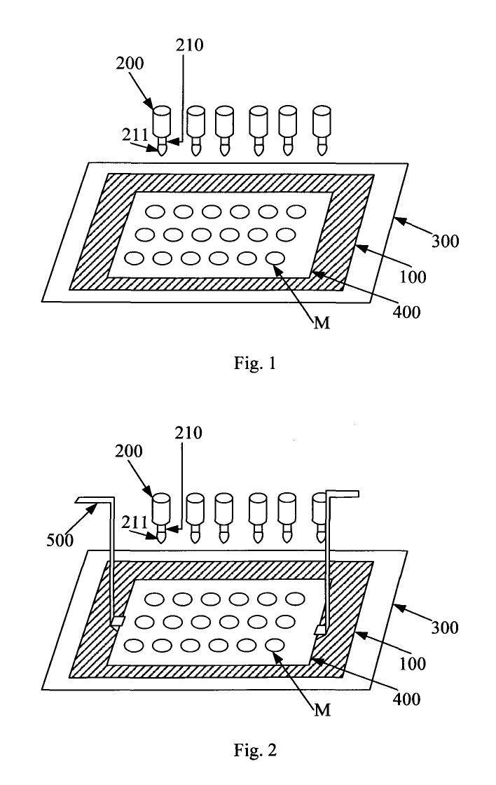

Embodiments of the present disclosure provide an encapsulation apparatus. As shown in FIG. 1, the encapsulation apparatus comprises: an attraction unit 100 and n adhesive-dripping units 200, and n is greater than or equal to 1.

Each of the adhesive-dripping units 200 contains adhesive glue, which includes an absorbable substance. Optionally, the adhesive glue is dam filler glue (i.e., filler glue).

The attraction unit 100 is disposed on a base platform 300, and the attraction unit 100 is configured to generate attraction for the absorbable substance in the adhesive glue 200 sprayed out from nozzles 210 of the glue ports of the adhesive-dripping units 200, so as to make the adhesive glue 211 spray to dotting positions M of the adhesive glue 211 on the encapsulation substrate 400 in a preset spraying amount from the nozzles 210 under the effect of the attraction.

To summarize, the encapsulation apparatus provided by an embodiment of the present disclosure comprises an attraction unit and n adhesive-dripping units; the adhesive-dripping units contain an absorbable substance; since the adhesive glue contains an absorbable substance, the attraction unit can generate attraction for the absorbable substance in the adhesive glue sprayed out from the nozzles of the glue ports of the adhesive-dripping units. The adhesive glue is sprayed to the dotting positions on the encapsulation substrate in a preset spraying amount from the nozzles under the effect of the attraction. Compared with the prior art, the adhesive glue is not easily adhered at the nozzles of the glue ports of the adhesive-dripping units, thus increasing the effect and efficiency of encapsulation.

In FIG. 1, the attraction unit 100 is disposed between the base platform 300 and the encapsulation substrate 400. In order to avoid deformation of the encapsulation substrate 400 due to the presence of the attraction unit 100, as shown in FIG. 2, the encapsulation substrate 400 may keep a certain distance from the attraction unit 100 under the effect of the support force of a support member 500. For the support member 500, reference may be made to support members in the prior art, and it will not be described in embodiments of the present disclosure herein. In addition, the other reference numerals in FIG. 2 may be described by referring to the reference numerals in FIG. 1.

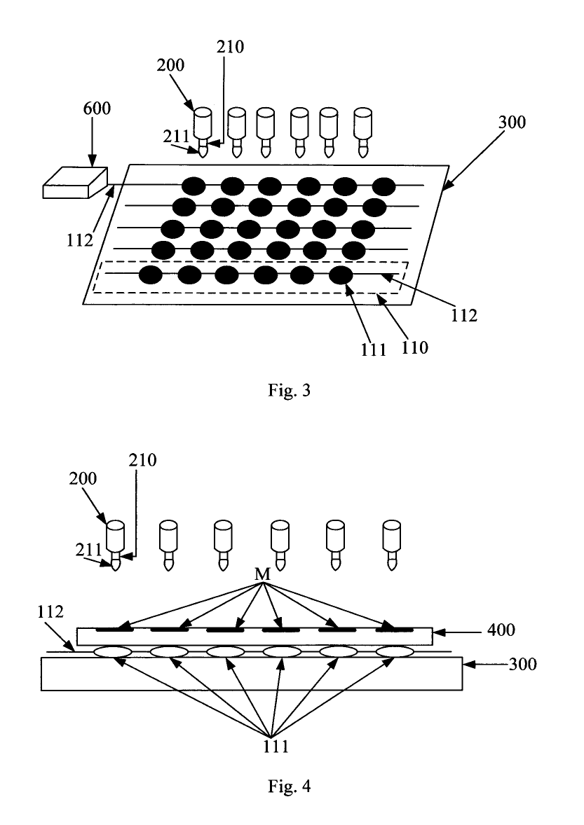

Optionally, the absorbable substance is a ferromagnetic substance. As shown in FIG. 3, the attraction unit comprises a plurality of electromagnet groups 110 arranged in an array, and each electromagnet group 110 comprises n (n is greater than or equal to 1) electromagnets 111. In FIG. 3, each electromagnet group comprises 6 electromagnets. For example, the electromagnet is circular-shaped, and the diameter of the electromagnet is 1 cm. The n electromagnets 111 are configured to generate attraction for the absorbable substance in the adhesive glue 211 sprayed out from the nozzles 210 of the glue ports of the adhesive-dripping units 200 after being energized, and to stop generating attraction for the absorbable substance in the adhesive glue 211 sprayed out from the nozzles 210 of the glue ports of the adhesive-dripping units 200 after being de-energized. The n electromagnets 111 in each electromagnet group 110 are connected through a wire 112. Reference numeral 300 in FIG. 3 denotes a base platform. FIG. 4 shows a side view of the attraction unit shown in FIG. 3. As shown in FIG. 4, an orthogonal projection of each electromagnet 111 on the encapsulation substrate 400 corresponds to a dotting position M of the adhesive glue on the encapsulation substrate 400. In FIG. 4, reference numeral 200 is the adhesive-dripping unit, reference numeral 210 is the nozzle, reference numeral 211 is the adhesive glue, reference numeral 300 is the base platform, and reference numeral 112 is the wire.

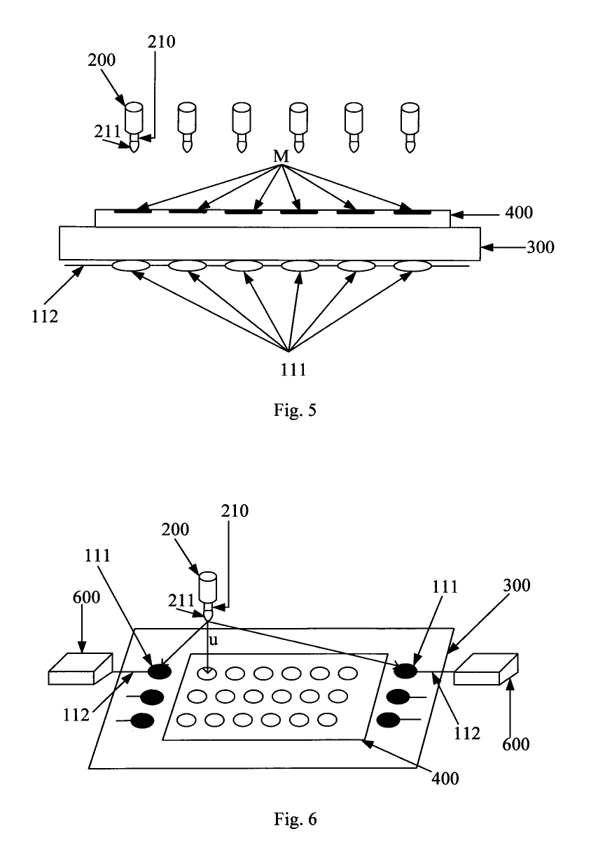

It should be noted additionally that as shown in FIG. 4, the plurality of electromagnet groups are disposed on the carrying surface of the base platform 300, and the carrying surface is for carrying the encapsulation substrate 400. Alternatively, the plurality of electromagnet groups can also be disposed on the surface of the base platform opposite to the carrying surface, as shown in FIG. 5. The plurality of electromagnet groups in FIG. 5 may be fixed on the surface of the base platform opposite to the carrying surface in various ways, and embodiments of the present disclosure have no limitation in this respect. The reference numerals in FIG. 5 may be described by referring to the reference numerals in FIG. 4, and will not be repeated here.

As shown in FIG. 3, the encapsulation apparatus may further comprise: a current generating unit 600. The current generating unit 600 is connected to the electromagnets through wires 112. The current generating unit 600 is configured to generate currents of different magnitudes. The electromagnets 111 in each electromagnet group 110 are configured to, after being energized, generate different attractions for the absorbable substance (i.e., the ferromagnetic substance) in the adhesive glue 211 sprayed out from the nozzles 210 under the control of currents of different magnitudes. For example, the current generating unit may be an adjustable current module, and embodiments of the present disclosure may generate currents of different magnitudes through the adjustable current module, so as to make the electromagnets generate different attractions for the adhesive glue sprayed out from the nozzles of the glue ports of the adhesive-dripping units. For the adjustable current module, reference may be made to the prior art, which is not repeated herein in embodiments of the present disclosure.

Supposing the adhesive glue is filler glue, the process of encapsulating the OLED display by the encapsulation apparatus shown in FIG. 3 may be as follows: placing the encapsulation substrate on the carrying surface of the base substrate provided with the attraction unit; coating a dam sealant on the encapsulation substrate, and then filling filler glue inside the dam sealant by the n glue-gripping units. Specifically, first the n electromagnets in the first electromagnet group are energized, and the n electromagnets in the first electromagnet group generate magnetism after being energized, and generate attraction for the ferromagnetic substance in the filler glue sprayed out from the nozzles of the glue ports of the n adhesive-dripping units. The filler glue sprayed out from the nozzles of the glue ports of the n adhesive-dripping units are accurately sprayed to the first group of dotting positions on the encapsulation substrate from the nozzles under the effect of the attraction. Then, the n electromagnets in the first electromagnet group are de-energized, and the magnetism of the n electromagnets in the first electromagnet group disappears after the being de-energized. The n electromagnets in the first electromagnet group stop generating attraction for the ferromagnetic substance in the filler glue sprayed out from the nozzles of the glue ports of the n adhesive-dripping units, and the n adhesive-dripping units stop spraying filler glue to the first group of dotting positions on the encapsulation substrate.

Then, in the same way, the encapsulation apparatus is used to spray filler glue to the other groups of dotting positions on the encapsulation substrate, thus finishing the dotting process of filler glue. Finally, the encapsulation substrate dotted with the filler glue and a base substrate provided with OLED devices are pressed together and cured, thus accomplishing the entire encapsulation process. In addition, when the dotting process of the filler glue is performed, currents of different magnitudes may be generated by the current generating unit, and the electromagnets in each electromagnet group generate different magnetism under the effect of the currents of different magnitudes, and generate different attractions for the ferromagnetic substance in the filler glue sprayed out from the nozzles of the glue ports of the n adhesive-dripping units, and the filler glue is accurately sprayed to the dotting positions on the encapsulation substrate from the nozzles under the effect of the different attractions. The main components of the dam sealant are epoxy resin, additives, optical initiators, and inorganic fillers; the main components of the filler glue are epoxy resin, additives, and optical initiators. The viscosity of the dam sealant is greater than that of the filler glue.

Embodiments of the present disclosure, by adding a ferromagnetic substance in the adhesive glue (e.g., filler glue), and setting electromagnets at positions under the encapsulation substrate corresponding to the dotting positions, using the current generating unit to generate currents of different magnitudes, which controls the magnetism of the electromagnets, so as to make the electromagnets generate different attractions for the ferromagnetic substance in the adhesive glue sprayed out from the nozzles of the glue ports of the adhesive-dripping units, provide that the adhesive glue is accurately sprayed to the dotting positions on the encapsulation substrate in a preset spraying amount under the effect of the attractions. Compared with the prior art, the adhesive glue is not easily adhered at the nozzles of the glue ports of the adhesive-dripping units, and glue will not be easily accumulated at the nozzles, thus enhancing the effect and efficiency of encapsulation of the OLED device.

Optionally, as shown in FIG. 6, each electromagnet group 110 may also comprise two electromagnets 111. The two electromagnets 111 are located at opposite sides of the region of the orthogonal projection of the encapsulation substrate 400 on the base platform 300. The direction of the resultant force of the attractions (the direction indicated by u in FIG. 6) generated by the two electromagnets 111 for the absorbable substance in the adhesive glue 211 sprayed out from the nozzle 210 of the glue port of the adhesive-dripping unit 200 is the same as the direction of gravity on the adhesive glue 211 sprayed out from the nozzle 210. In FIG. 6, reference numeral 112 is a wire, and reference numeral 600 is a current generating unit; the current generating unit 600 is configured to generate currents of different magnitudes; the electromagnets 111 are configured to generate different attractions for the absorbable substance in the adhesive glue 211 sprayed out from the nozzle 210 under the control of different currents after being energized. Also, the plurality of electromagnet groups in FIG. 6 may be disposed on the carrying surface of the base platform, or on the surface of the base platform opposite to the carrying surface.

Supposing that the adhesive glue is filler glue, the process of encapsulating the OLED display by the encapsulation apparatus shown in FIG. 6 may be as follows: disposing the encapsulation substrate on a carrying surface of the base platform provided with the absorbing unit; first, coating a dam sealant on the encapsulation substrate, and then filling the filler glue inside the dam sealant by an adhesive-dripping unit; specifically, first the two electromagnets in the first group of electromagnets are energized by the current generating unit; and the two electromagnets in the first electromagnet group generate magnetism after being energized, and generate attraction for the ferromagnetic substance in the filler glue sprayed out from the nozzle of the glue port of the adhesive-dripping unit; the adhesive-dripping unit is above the first dotting position of the first group of dotting positions. The two electromagnets generate attractions of different magnitudes and different directions for the ferromagnetic substance in the filler glue, and the direction of the resultant force of the two attractions is the same as the direction of gravity on the filler glue sprayed out from the nozzle. In this way, the filler glue sprayed out from the nozzle may be accurately sprayed to the first dotting position in the first group of dotting positions on the encapsulation substrate from the nozzle under the effect of the resultant force of the filler glue sprayed out from the nozzle. Then the two electromagnets in the first group of electromagnets are de-energized by the current generating unit; the magnetism of the two electromagnets in the first group of electromagnets disappears after the being de-energized, and the two electromagnets in the first group of electromagnets stop generating attraction for the ferromagnetic substance in the filler glue sprayed out from the nozzle, and the adhesive-dripping unit stops spraying the filler glue to the first dotting position in the first group of dotting positions on the encapsulation substrate.

Then, in the same way, the filler glue is sprayed to the other dotting positions in the first group of dotting positions and other groups of dotting positions by using the encapsulation apparatus, thus finishing the dotting process of the filler glue. When the filler glue is sprayed to the other dotting positions in the first group of dotting positions and other groups of dotting positions, first the magnitudes of the attractions of two electromagnets that the filler glue should take may be determined according to the gravity direction of the filler glue, and the magnitude of the magnetism of the two electromagnets may be determined according to the magnitudes of the attractions of the two electromagnets, and finally the magnitudes of the currents that should be output by the current generating unit may be determined according to the magnitudes of the magnetism of the two electromagnets. After the magnitudes of the currents that should be outputted by the current generating unit are determined, the two electromagnets in the electromagnet groups may be energized by the current generating unit. Finally, the encapsulation substrate dotted with the filler glue and a base substrate disposed with OLED devices are pressed together and cured, and the entire encapsulation process is accomplished.

Embodiments of the present disclosure, by adding a ferromagnetic substance in the adhesive glue (e.g., filler glue), and disposing electromagnets at both sides of the region of the orthogonal projection of the encapsulation substrate on the base platform, generating currents of different magnitudes by the current generating unit, and controlling the magnetism of the electromagnets, makes the electromagnets generate two attraction forces with different magnitudes and different directions for the ferromagnetic substance in the adhesive glue sprayed out from the nozzle of the glue port of the adhesive-dripping unit, and the direction of the resultant force of the two attractions is the same as the direction of the gravity on the filler glue sprayed out from the nozzle, such that the filler glue sprayed out from the nozzle is accurately sprayed to the dotting positions of the adhesive glue on the encapsulation substrate under the effect of the resultant force. Compared with the prior art, the adhesive glue is not easily adhered at the nozzles of the glue ports of the adhesive-dripping units, and the glue is not easily accumulated at the nozzles, thus enhancing the effect and efficiency of encapsulating the OLED devices.

To summarize, embodiments of the present disclosure provide an encapsulation apparatus. The encapsulation apparatus comprising an attraction unit and n adhesive-dripping units; the adhesive-dripping units contain adhesive glue. Since the adhesive glue includes an absorbable substance, the attraction unit can generate attraction force for the absorbable substance in the adhesive glue sprayed out from the nozzle of the glue ports of the adhesive-dripping unit; the adhesive glue is sprayed to dotting positions on the encapsulation substrate in a preset spraying amount from the nozzles under the effect of the attraction; compared with the prior art, the adhesive glue is not easily adhered at the nozzles of the glue ports of the adhesive-dripping unit, thus enhancing the effect and efficiency of encapsulation of the OLED devices.

Above are merely described certain embodiments of the present disclosure, which are not intended to restrict the present disclosure. Any amendments, equivalent replacements and improvements made within the spirits and principles of the present disclosure should be included in the protection scope of the present disclosure.

1. An encapsulation apparatus, wherein the encapsulation apparatus comprises:
an attraction unit and n adhesive-dripping units, n being greater than or equal to 1, wherein:
each of the adhesive-dripping units contains adhesive glue, the adhesive glue including an absorbable substance; and
the attraction unit is disposed on a base platform, and is configured to generate attraction for the absorbable substance in the adhesive glue sprayed out from nozzles of the adhesive-dripping units, such that the adhesive glue is sprayed to dotting positions of the adhesive glue on an encapsulation substrate in a preset spraying amount under the effect of the attraction.

2. The encapsulation apparatus of claim 1, wherein,
the absorbable substance is a ferromagnetic substance;
the attraction unit comprises a plurality of electromagnet groups arranged in an array, each of the electromagnet groups comprising n electromagnets, the n electromagnets being configured to generate attraction for the absorbable substance in the adhesive glue sprayed out from the nozzles after being energized, and to stop generating attraction for the absorbable substance in the adhesive glue sprayed out from the nozzle after being de-energized.

3. The encapsulation apparatus of claim 2, wherein,
an orthogonal projection of each electromagnet on the encapsulation substrate corresponds to a dotting position of the adhesive glue on the encapsulation substrate.

4. The encapsulation apparatus of claim 1, wherein,
the absorbable substance is a ferromagnetic substance;
the attraction unit comprises a plurality of electromagnet groups arranged in an array, each of the electromagnet groups comprising two electromagnets, the two electromagnets being configured to generate attraction for the absorbable substance in the adhesive glue sprayed out from the nozzles after being energized, and to stop generating attraction for the absorbable substance in the adhesive glue sprayed out from the nozzle after being de-energized, the two electromagnets being located at opposite sides of the region of the orthogonal projection of the encapsulation substrate on the base platform, and operable such that the direction of the resultant force of the attractions generated by the two electromagnets for the absorbable substance in the adhesive glue is the same as the direction of gravity on the adhesive glue sprayed out from the nozzle.

5. The encapsulation apparatus of claim 2, characterized by one of the following:
the plurality of electromagnet groups are disposed on a carrying surface of the base platform, the carrying surface being configured to carry the encapsulation substrate; and
the plurality of electromagnet groups are disposed on a surface of the base platform opposite to the carrying surface.

6. The encapsulation apparatus of claim 5, wherein the encapsulation apparatus further comprises a current generating unit,
the current generating unit is configured to generate currents of different magnitudes,
the electromagnets in each electromagnet group are further configured to, after being energized, generate different attractions for the absorbable substance in the adhesive glue sprayed out from the nozzle under the control of the currents of different magnitudes.

7. The encapsulation apparatus of claim 5, wherein at least one electromagnet is circular-shaped.

8. The encapsulation apparatus of claim 7, wherein a diameter of the at least one electromagnet is 1 cm.

9. The encapsulation apparatus of claim 3, characterized by one of the following:
the plurality of electromagnet groups are disposed on a carrying surface of the base platform, the carrying surface being configured to carry the encapsulation substrate; and
the plurality of electromagnet groups are disposed on a surface of the base platform opposite to the carrying surface.

10. The encapsulation apparatus of claim 9, wherein the encapsulation apparatus further comprises a current generating unit,
the current generating unit is configured to generate currents of different magnitudes,
the electromagnets in each electromagnet group are further configured to, after being energized, generate different attractions for the absorbable substance in the adhesive glue sprayed out from the nozzle under the control of the currents of different magnitudes.

11. The encapsulation apparatus of claim 9, wherein at least one electromagnet is circular-shaped.

12. The encapsulation apparatus of claim 11, wherein a diameter of the at least one electromagnet is 1 cm.

13. The encapsulation apparatus of claim 4, characterized by one of the following:
the plurality of electromagnet groups are disposed on a carrying surface of the base platform, the carrying surface being configured to carry the encapsulation substrate; and
the plurality of electromagnet groups are disposed on a surface of the base platform opposite to the carrying surface.

14. The encapsulation apparatus of claim 13, wherein the encapsulation apparatus further comprises a current generating unit,
the current generating unit is configured to generate currents of different magnitudes,
the electromagnets in each electromagnet group are further configured to, after being energized, generate different attractions for the absorbable substance in the adhesive glue sprayed out from the nozzle under the control of the currents of different magnitudes.

15. The encapsulation apparatus of claim 13, wherein at least one electromagnet is circular-shaped.

16. The encapsulation apparatus of claim 15, wherein a diameter of the at least one electromagnet is 1 cm.

17. The encapsulation apparatus of claim 1, wherein,
the adhesive glue is a dam filler glue.
